(19) United States
(12) Patent Application Publication
(10) Pub. No.: US 2026/0230058 A1
(43) Pub. Date: Aug. 6, 2026

(54) RESONATOR DEVICE

(71) Applicant: SEIKO EPSON CORPORATION, Tokyo (JP)

(72) Inventors: Yusuke Yamamoto, Minowa-machi (JP); Akinori Yamada, Ina-shi (JP)

(21) Appl. No.: 19/529,651

(22) Filed: Feb. 4, 2026

(30) Foreign Application Priority Data
Feb. 6, 2025 (JP) 2025-018180

(51) Int. Cl. H03H 9/19; H03H 9/05

(52) U.S. Cl. CPC H03H 9/19; H03H 9/0538

(57) ABSTRACT

A resonator device includes: a resonator that includes a vibrating section that is a quadrangle including a first side and a second side intersecting with each other in a plan view, and a support section including a first support portion along the first side and a second support portion along the second side and having a thickness greater than a thickness of the vibrating section; a base to which the resonator is attached; a first metal bump that is disposed in a region overlapping the first support portion of the resonator in a plan view and joins the resonator and the base; and a second metal bump that is disposed in a region overlapping the second support portion of the resonator in a plan view and joins the resonator and the base.

The present application is based on, and claims priority from JP Application Serial Number 2025-018180, filed February 6, 2025, the disclosure of which is hereby incorporated by reference herein in its entirety.

### BACKGROUND

### Technical Field

The present disclosure relates to a resonator device.

### Related Art

JP-A-2014-175802 discloses a structure of an electronic component in which a quartz crystal resonator element is fixed to a base substrate by disposing a bump

electrode at each of a first support point and a second support point supported in a diagonal direction of the quartz crystal resonator element. By forming a groove portion between the first support point and the bump electrode and between the second support point and the bump electrode, the application of unnecessary stress to an excitation electrode provided in the quartz crystal resonator element and the deterioration of vibration characteristics can be suppressed.

However, in the configuration described in JP-A-2014-175802, since the groove portion is formed in the flat plate-shaped quartz crystal resonator element, there is a problem in that the strength of the quartz crystal resonator element is lowered.

### SUMMARY

According to an aspect of the present disclosure, there is provided a resonator device including: a resonator that includes a vibrating section that is a quadrangle including a first side and a second side intersecting with each other in a plan view, and a support section including a first portion along the first side and a second portion along the second side and having a thickness greater than a thickness of the vibrating section; a base to which the resonator is attached; a first joining member that is disposed in a region overlapping the first portion of the resonator in a plan view and joins the resonator and the base; and a second joining member that is disposed in a region overlapping the second portion of the resonator in a plan view and joins the resonator and the base.

### BRIEF DESCRIPTION OF THE DRAWINGS

FIG. 1 is a perspective view illustrating a configuration of a resonator device.

FIG. 2 is a sectional view illustrating the configuration of the resonator device.

FIG. 3 is a plan view illustrating the configuration of the resonator device.

FIG. 4 is a sectional view illustrating the configuration of the resonator device.

FIG. 5 is a plan view illustrating the configuration of the resonator device.

FIG. 6 is a perspective view illustrating a configuration of a resonator.

FIG. 7 is a diagram for describing a relationship between an AT cut quartz crystal substrate and a crystal

axis of quartz crystal.

FIG. 8 is a plan view illustrating the configuration of the resonator.

FIG. 9 is a plan view illustrating the configuration of the resonator.

FIG. 10A is a plan view illustrating a configuration of a resonator of a comparative example.

FIG. 10B is a plan view illustrating a configuration of a resonator of the comparative example.

FIG. 10C is a plan view illustrating a configuration of a resonator of the comparative example.

FIG. 11 is a graph illustrating a relationship between a mounting angle of a metal bump and frequency fluctuation.

FIG. 12 is a sectional view illustrating a configuration of a resonator of a modification example.

### DESCRIPTION OF EMBODIMENTS

Hereinafter, the configuration of a resonator device 100 will be described with reference to the drawings. In each of the following drawings, three axes orthogonal to each other are described as an X axis, a Y’ axis, and a Z’ axis. A direction along the X axis is referred to as an “X direction”, a direction along the Y’ axis is referred to as a “Y’-axis direction”, and a direction along the Z’ axis is referred to as a “Z’-axis direction”. A direction of an arrow is a + direction, and a direction opposite to the + direction is a - direction. A plan view from the Y’-axis direction is also simply referred to as a “plan view”.

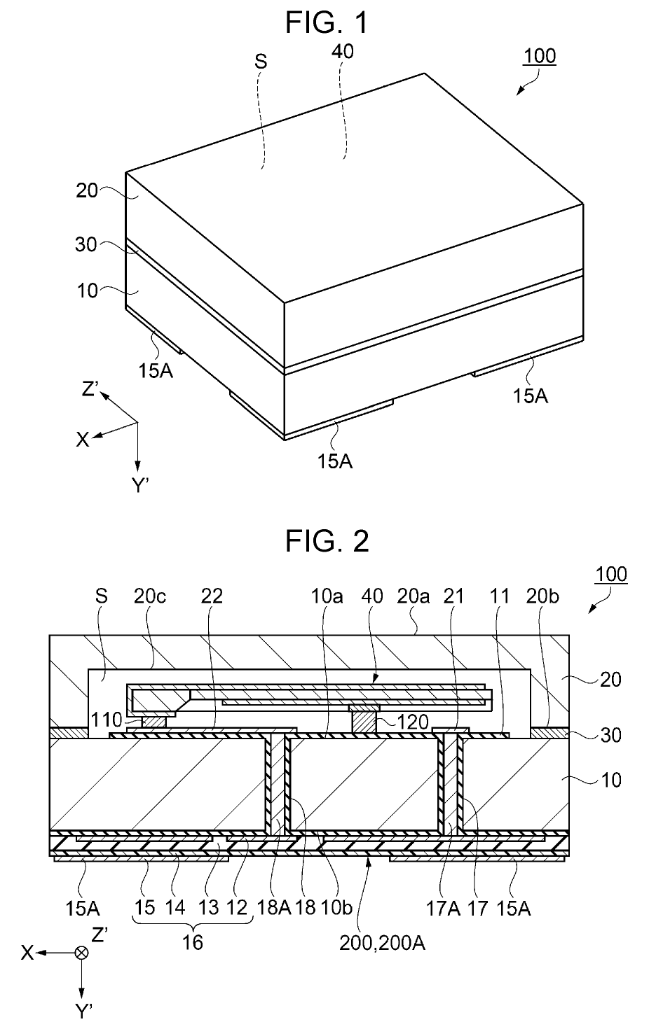

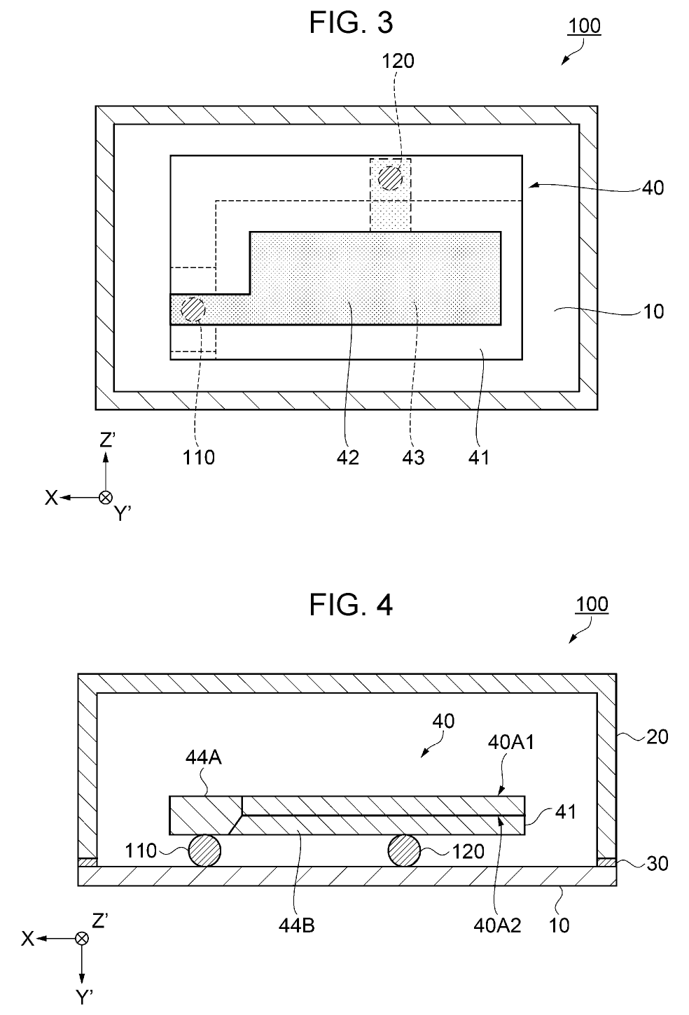

First, the configuration of the resonator device 100 will be described with reference to FIGS. 1 to 3. The resonator device 100 illustrated in FIG. 3 illustrates a state where a lid 20 is removed for convenience of description of the internal configuration.

As illustrated in FIG. 1, the resonator device 100 includes a base 10, the lid 20 disposed on the base 10, a joining layer 30 that joins the base 10 and the lid 20, and a resonator 40 mounted on the base 10.

As illustrated in FIGS. 1 and 2, the resonator device 100 has an airtight accommodation portion S. The resonator 40 is accommodated in the accommodation portion S. The resonator device 100 includes the base 10 to which the resonator 40 is joined via metal bumps 110 and 120 as a pair of joining members, and the lid 20 that is joined to an upper surface 10a of the base 10 to cover the resonator 40. An integrated circuit 200 that includes an oscillation circuit 200A that causes the resonator 40 to oscillate is disposed on a lower surface 10b side of the base 10.

The base 10 is a silicon substrate. In the present embodiment, particularly, a P-type silicon substrate is used. Therefore, when the resonator device 100 is used, the base 10 is coupled to the ground, which is a constant potential. However, the base 10 is not particularly limited, and may be an N-type silicon substrate. In addition, a semiconductor substrate other than silicon, for example, a semiconductor substrate such as Ge, GaP, GaAs, or InP may be used.

The base 10 has a plate shape and has the upper surface 10a and the lower surface 10b that are in a front-back relationship. An insulating film 11 is formed on each of the upper surface 10a and the lower surface 10b of the base 10. The insulating film 11 is, for example, a silicon oxide film formed by thermally oxidizing the surface of the base 10. However, the insulating film 11 is not particularly limited, and may be, for example, a silicon nitride film. The method of forming the insulating film 11 is not limited to thermal oxidation, and may be, for example, chemical vapor deposition (CVD).

The integrated circuit 200 that is electrically coupled to the resonator 40 is disposed on the lower surface 10b side of the base 10. In this manner, the integrated circuit 200 is disposed on the base 10, so that the base 10 can be effectively utilized. In particular, by disposing the integrated circuit 200 on the lower surface 10b side, as compared with a case where the integrated circuit 200 is disposed on the upper surface 10a side, the space for disposing the integrated circuit 200 can be secured more widely because there is no joining region to the lid 20.

The integrated circuit 200 includes the oscillation circuit 200A that is electrically coupled to the resonator 40 and generates an oscillation signal such as a clock signal by causing the resonator 40 to oscillate. The integrated circuit 200 may include a circuit other than the oscillation circuit 200A. As the circuit, a processing circuit that processes an output signal from the oscillation circuit 200A can be given as an example, and as such a processing circuit, a PLL circuit can be given as an example.

In this manner, since the oscillation circuit 200A that excites the resonator 40 is disposed on the base 10, the resonator device 100 including an oscillator, in which the strength of the resonator 40 can be maintained and frequency fluctuation ΔF due to mounting stress is reduced, can be provided.

A laminated body 16 in which a wire layer 12, an insulating layer 13, a passivation film 14, and a terminal layer 15 are laminated is disposed on the lower surface 10b of the base 10. The integrated circuit 200 is configured by electrically coupling a plurality of active elements (not illustrated) formed on the lower surface 10b via a wire included in the wire layer 12. The terminal layer 15 has a plurality of mounting terminals 15A electrically coupled to the integrated circuit 200. In the resonator device 100, the integrated circuit 200 and an external device are coupled to each other via the mounting terminal 15A.

A pair of through-holes 17 and 18 penetrating the base 10 in a thickness direction are formed in the base 10. Each of the through-holes 17 and 18 is filled with a conductive material such as a metal material, and thus through electrodes 17A and 18A are formed in the through-holes 17 and 18.

A pair of wires 21 and 22 electrically coupled to the resonator 40 are disposed on the upper surface 10a of the base 10. The wire 21 is electrically coupled to the integrated circuit 200 via the through electrode 17A. The wire 22 is electrically coupled to the integrated circuit 200 via the through electrode 18A.

The lid 20 is, for example, a silicon substrate, like the base 10. In this way, the linear expansion coefficients of the base 10 and the lid 20 become equal to each other, the generation of thermal stress due to thermal expansion is suppressed, and the resonator device 100 having excellent vibration characteristics is obtained. In addition, since the resonator device 100 can be formed by a semiconductor process, the resonator device 100 can be manufactured with high accuracy and can be downsized. However, the lid 20 is not particularly limited, and a semiconductor substrate other than silicon, for example, a semiconductor substrate such as Ge, GaP, GaAs, or InP may be used.

As illustrated in FIG. 1, the lid 20 has a box shape. As illustrated in FIG. 2, the lid 20 has an upper surface 20a, a lower surface 20b, and a bottomed recessed portion 20c that is open on the lower surface 20b and accommodates the resonator 40 inside.

The lid 20 is joined to the upper surface 10a of the base 10 via the joining layer 30 on the lower surface 20b. The base 10 and the lid 20 are joined to each other via the joining layer 30, so that the base 10 and the lid 20 can be strongly and tightly joined to each other. Therefore, the strength of the resonator device 100 can be increased, and the airtightness of the accommodation portion S can be increased.

As illustrated in FIG. 3, the resonator 40 includes a quartz crystal substrate 41, a first excitation electrode 42 disposed on one surface 40A1 of the quartz crystal substrate 41, and a second excitation electrode 43 disposed on the other surface 40A2 of the quartz crystal substrate 41. A specific configuration of the resonator 40 will be described later.

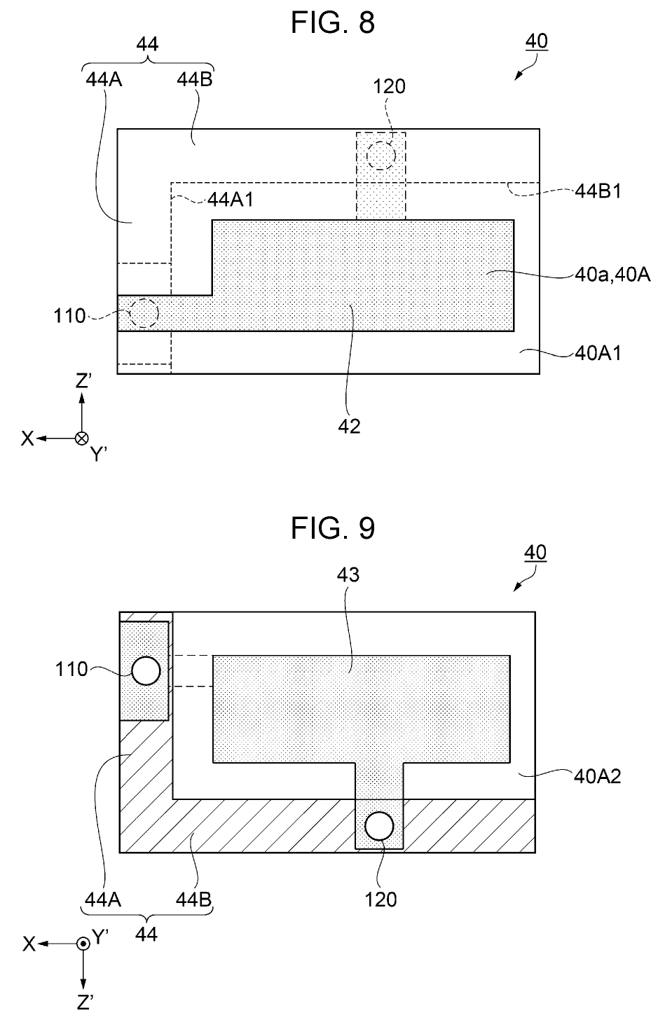

Next, the configuration of the resonator device 100 will be specifically described with reference to FIGS. 4 to 9. FIG. 4 does not show the integrated circuit 200 and the like disposed on the base 10. Further, FIG. 8 is a view of the resonator 40 as viewed from the -Y' direction. FIG. 9 is a view of the resonator 40 as viewed from the +Y’ direction.

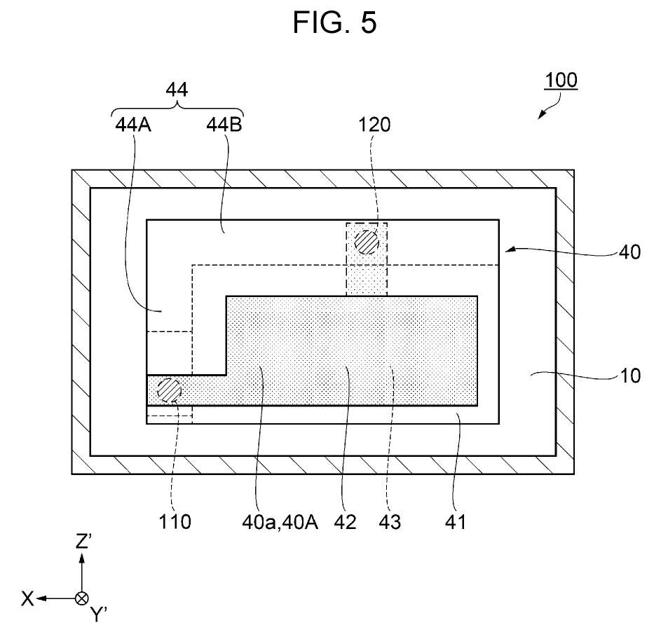

As illustrated in FIGS. 4 and 5, the resonator device 100 includes the base 10, the lid 20 disposed on the base 10, the joining layer 30 that joins the base 10 and the lid 20, and the resonator 40 mounted on the base 10.

As illustrated in FIGS. 4 to 6, the resonator 40 includes the quartz crystal substrate 41 having a vibrating section 40A including a vibrating region 40a and a support section 44 having a thickness greater than a thickness of the vibrating section 40A. The vibrating section 40A is a quadrangle including a first side and a second side that intersect with each other in a plan view. The support section 44 has a first support portion 44A as a first portion along the first side, and a second support portion 44B as a second portion along the second side. In addition, the resonator 40 includes the excitation electrodes 42 and 43 disposed on the vibrating section 40A.

The quartz crystal substrate 41 is a plate-shaped substrate. The quartz crystal substrate 41 is quartz crystal. The resonator 40, specifically, the quartz crystal substrate 41 has a rectangular shape in which in a plan view, an outer edge on a side of the first support portion 44A is a short side as the first side and an outer edge on a side of the second support portion 44B is a long side as the second side.

As illustrated in FIG. 7, the quartz crystal, which is a material of the quartz crystal substrate 41, belongs to a trigonal system, and has crystal axes X, Y, and Z orthogonal to each other. The X axis, the Y axis, and the Z axis are referred to as an electrical axis, a mechanical axis, and an optical axis, respectively. The quartz crystal substrate 41 of the present embodiment is a "rotated Y cut quartz crystal substrate" cut out along a plane obtained by rotating the XZ plane by a predetermined angle θ around the X axis, and for example, a substrate when cut out along a plane obtained by rotating the XZ plane by θ = 35°15' is referred to as an "AT cut quartz crystal substrate". The resonator 40 having excellent temperature characteristics is obtained by using the quartz crystal substrate 41 as described above.

However, the quartz crystal substrate 41 is not limited to the AT cut quartz crystal substrate as long as thickness-shear vibration can be excited, and for example, a BT cut quartz crystal substrate may be used. In the following, the Y axis and the Z axis rotated around the X axis corresponding to the angle θ are referred to as a Y' axis and a Z' axis. That is, the quartz crystal substrate 41 has a thickness in the Y' direction and extends in an XZ' plane direction. The quartz crystal substrate 41 has an elongated shape in which the X direction is a long side and the Z' direction is a short side in a plan view. Further, the quartz crystal substrate 41 has the -X direction as a tip end side and the +X direction as a base end side.

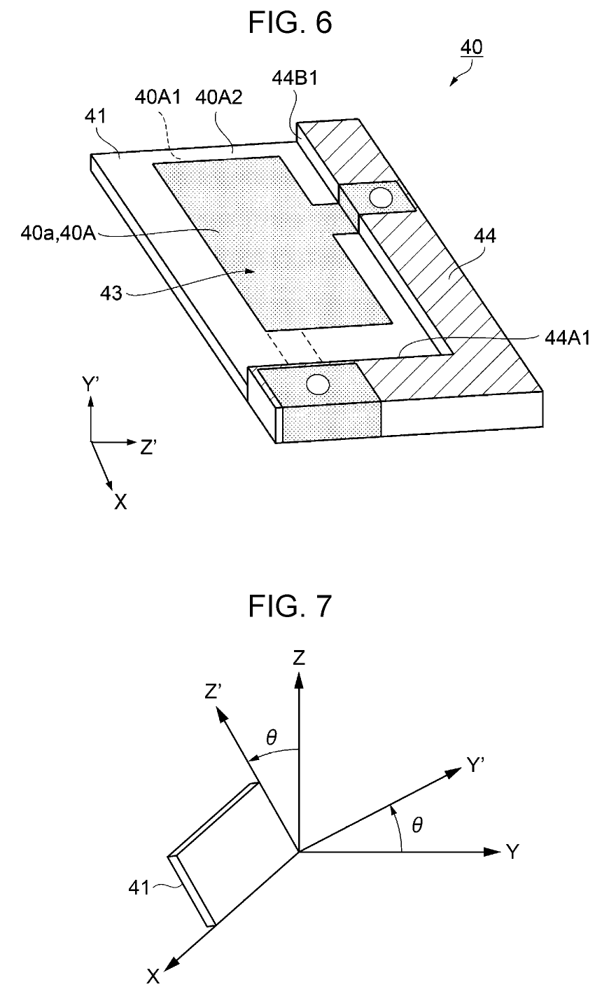

As illustrated in FIGS. 6, 8, and 9, the quartz crystal substrate 41 configuring the resonator 40 includes the vibrating section 40A including the vibrating region 40a which is a region where the vibration energy is confined, and the support section 44 which is integrated with the vibrating section 40A and has a thickness greater than a thickness of the vibrating section 40A.

The vibrating section 40A is shifted in the -X direction and the -Z' direction with respect to the center of the quartz crystal substrate 41, and a part of the outer edge thereof is exposed from the support section 44. The area of the vibrating section 40A is preferably 1/2 or less of the area of the quartz crystal substrate 41 in a plan view. In this way, the support section 44 having a high mechanical strength can be formed to be sufficiently wide, and thus the rigidity of the vibrating section 40A can be sufficiently secured.

The support section 44 protrudes with respect to the vibrating section 40A on the other surface 40A2 of the vibrating section 40A. Specifically, a main surface in the +Y' direction of the support section 44 is provided to protrude in the +Y' direction from the other surface 40A2, which is a main surface in the +Y' direction of the vibrating section 40A. On the other hand, a main surface in the -Y' direction of the support section 44 is provided on the same plane as one surface 40A1, which is a main surface in the -Y' direction of the vibrating section 40A.

The support section 44 includes the first support portion 44A that is coupled to an outer edge in the +X direction of the vibrating section 40A, and the second support portion 44B that is coupled to an outer edge in the +Z' direction of the vibrating section 40A. Therefore, the support section 44 has a structure that is bent along the vibrating section 40A in a plan view, and has a substantially L shape. Therefore, the mass of the resonator 40 on the tip end side can be reduced while maintaining the rigidity of the vibrating section 40A of the resonator 40. In addition, the resonator 40 can be downsized.

The support section 44 includes a connection portion 44B1 that couples the support section 44 and the vibrating section 40A to each other, is provided along the outer edge in the +Z’ direction of the vibrating section 40A, and has an inclined portion having a thickness which gradually increases toward the +Z’ direction, and a connection portion 44A1 that is provided along the outer edge in the +X direction of the vibrating section 40A and has an inclined portion having a thickness which gradually increases toward the +X direction.

As described above, the resonator 40 includes the first excitation electrode 42 disposed on one surface 40A1 of the quartz crystal substrate 41, and the second excitation electrode 43 disposed on the other surface 40A2 of the quartz crystal substrate 41. The first excitation electrode 42 and the second excitation electrode 43 are disposed in the vibrating section 40A.

As illustrated in FIG. 8, an electrode drawn out from the first excitation electrode 42 extends to the first support portion 44A, turns around to the other surface 40A2 side of the first support portion 44A, and is electrically coupled to the first metal bump 110 as the first joining member. In other words, the first metal bump 110 is disposed at a position overlapping the first support portion 44A in a plan view.

As illustrated in FIG. 9, an electrode drawn out from the second excitation electrode 43 extends to a region overlapping the second support portion 44B in a plan view, and is electrically coupled to the second metal bump 120 as the second joining member. In other words, the second metal bump 120 is disposed at a position overlapping the second support portion 44B in a plan view. The first metal bump 110 and the second metal bump 120 are made of, for example, gold (Au), and are joined to the base 10.

In this manner, the resonator 40 and the base 10 are joined by using the metal bumps 110 and 120. Therefore, for example, as compared with a case where the resonator 40 and the base 10 are joined by an adhesive, the metal bumps 110 and 120 do not spread around, and thus the resonator 40 and the base 10 can be joined at a predetermined position and the joint strength can be improved.

As a constituent material for the first excitation electrode 42 and the second excitation electrode 43, for example, a metal material such as gold (Au), silver (Ag), platinum (Pt), palladium (Pd), iridium (Ir), copper (Cu), aluminum (Al), nickel (Ni), chromium (Cr), titanium (Ti), or tungsten (W), and an alloy containing these metal materials can be used.

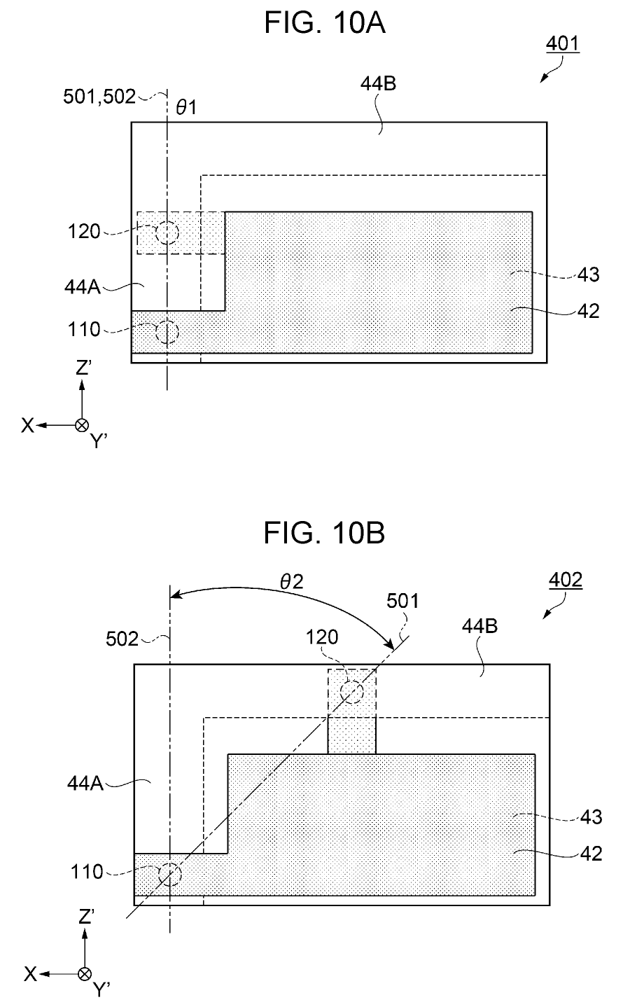

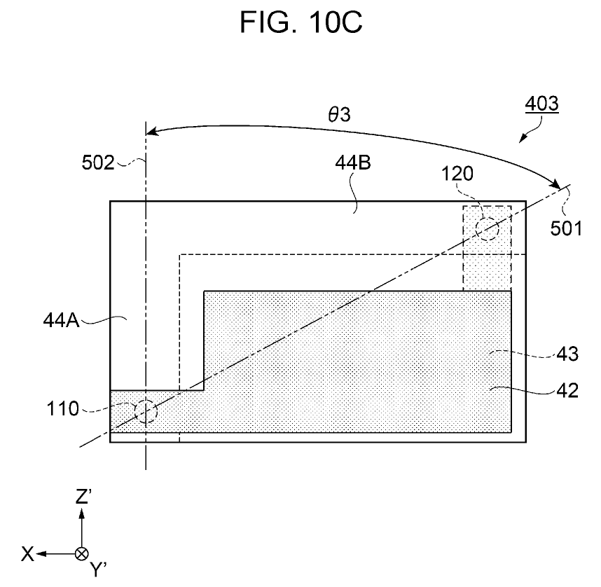

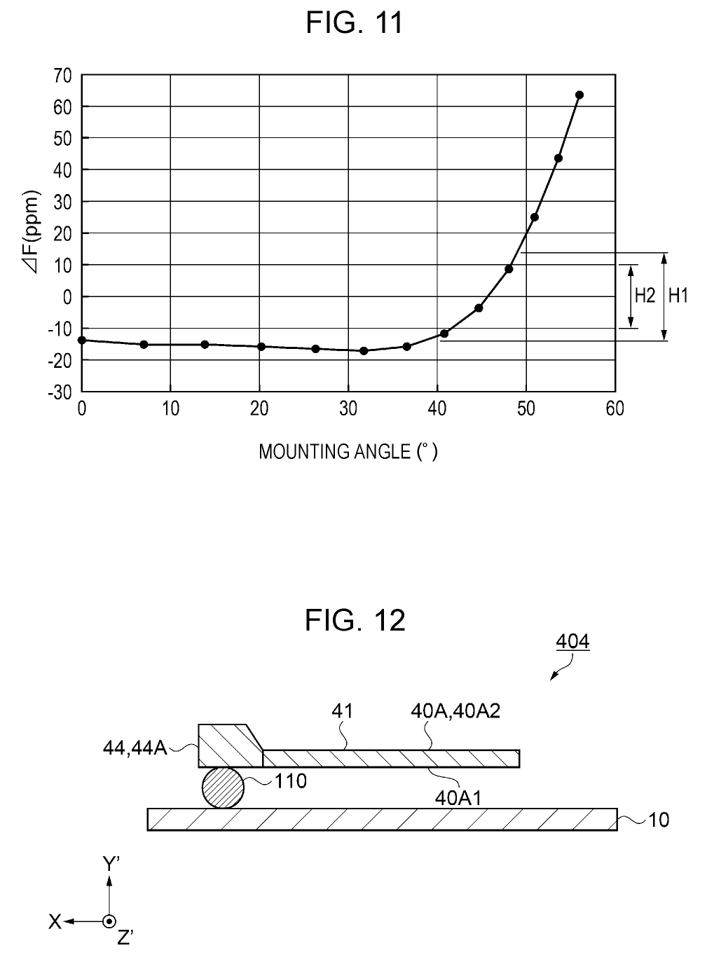

Next, a relationship between the disposition positions of the first metal bump 110 and the second metal bump 120 and the frequency fluctuation ΔF will be described with reference to FIGS. 10A, 10B, 10C, and 11. Resonators 401, 402, and 403 described below have the same configuration as the resonator 40 described above, except that the disposition positions of the pair of metal bumps 110 and 120 are changed.

In addition, in a plan view, an angle formed by a first imaginary line 501 passing through the center of the first metal bump 110 and the center of the second metal bump 120 and a second imaginary line 502 along the short side is set to angles θ1, θ2, and θ3.

In the resonator 401 illustrated in FIG. 10A, both the first metal bump 110 and the second metal bump 120 are disposed at positions overlapping the first support portion 44A in a plan view. Therefore, the angle θ1 is 0°.

In the resonator 402 illustrated in FIG. 10B, the first metal bump 110 is disposed at a position overlapping the first support portion 44A in a plan view, and the second metal bump 120 is disposed at a position overlapping the second support portion 44B in a plan view. The angle θ2 between the first metal bump 110 and the second metal bump 120 is, for example, 45°.

In the resonator 403 illustrated in FIG. 10C, the first metal bump 110 is disposed at a position overlapping the first support portion 44A in a plan view, and the second metal bump 120 is disposed at a position overlapping the second support portion 44B in a plan view. The angle θ3 between the first metal bump 110 and the second metal bump 120 is, for example, 56°. As described above, the frequency fluctuations ΔF of the three types of resonators 401, 402, and 403 are compared.

The graph shown in FIG. 11 illustrates the angle θ between the first metal bump 110 and the second metal bump 120 on the horizontal axis, and illustrates the value of the frequency fluctuation ΔF on the vertical axis.

For example, in the resonator 401 in which the angle θ1 between the first metal bump 110 and the second metal bump 120 is 0°, the frequency fluctuation ΔF is approximately -14 ppm. In the resonator 402 in which the angle θ2 between the first metal bump 110 and the second metal bump 120 is 45°, the frequency fluctuation ΔF is approximately -3 ppm. In the resonator 403 in which the angle θ3 between the first metal bump 110 and the second metal bump 120 is 56°, the frequency fluctuation ΔF is approximately +63 ppm. A diagram obtained in this way, which illustrates the relationship between the angle between the metal bumps 110 and 120 and the frequency fluctuation ΔF, is a graph shown in FIG. 11.

The resonator device 100 is desired to have the frequency fluctuation ΔF in a range H1 of ±12.5 ppm. Therefore, it is preferable that the angle θ between the first metal bump 110 and the second metal bump 120 satisfies a relational expression of 40° ≤ θ ≤ 49°. In this manner, since the angle θ is set to satisfy the above relational expression, the frequency fluctuation ΔF due to the mounting stress can be suppressed to 12.5 ppm or less, and the deterioration of the vibration characteristics can be suppressed.

In addition, in the resonator device 100 that is desired to have high vibration characteristics, it is desired to bring the frequency fluctuation ΔF into the range H2 of ±10 ppm. Therefore, it is preferable that the angle θ between the first metal bump 110 and the second metal bump 120 satisfies a relational expression of 42° ≤ θ ≤ 48°. In this manner, since the angle θ is set to satisfy the above relational expression, the frequency fluctuation ΔF due to the mounting stress can be suppressed to 10 ppm or less, and the deterioration of the vibration characteristics can be suppressed.

As described above, since the first metal bump 110 and the second metal bump 120 are disposed at diagonal positions with a predetermined angle with respect to the resonator 40, the distance between the first metal bump 110 and the second metal bump 120 can be sufficiently secured, and the resonator 40 can be stably joined to the base 10. Furthermore, since the first metal bump 110 and the second metal bump 120 are disposed on the first support portion 44A and the second support portion 44B each having a great thickness, the strength of the resonator 40 can be maintained, and the deterioration of the vibration characteristics can be suppressed.

As described above, the resonator device 100 of the present embodiment includes: the resonator 40 that includes the vibrating section 40A that is a quadrangle including the first side and the second side intersecting with each other in a plan view, and the support section 44 including the first support portion 44A along the first side and the second support portion 44B along the second side and having a thickness greater than a thickness of the vibrating section 40A; the base 10 to which the resonator 40 is attached; the first metal bump 110 that is disposed in a region overlapping the first support portion 44A of the resonator 40 in a plan view and joins the resonator 40 and the base 10; and the second metal bump 120 that is disposed in a region overlapping the second support portion 44B of the resonator 40 in a plan view and joins the resonator 40 and the base 10.

According to this configuration, the resonator 40 and the base 10 are joined by the first metal bump 110 disposed in the region overlapping the first support portion 44A along the first side in a plan view and the second metal bump 120 disposed in the region overlapping the second support portion 44B along the second side intersecting the first side in a plan view, and the first metal bump 110 and the second metal bump 120 are disposed at diagonal positions with respect to the resonator 40. Therefore, the distance between the first metal bump 110 and the second metal bump 120 can be sufficiently secured, and the resonator 40 and the base 10 can be joined with increased mounting strength of the resonator 40 to the base 10. Further, since the first metal bump 110 and the second metal bump 120 are disposed on the support section 44 having a great thickness, the strength of the resonator 40 can be maintained and the deterioration of the vibration characteristics can be suppressed.

In the resonator device 100 of the present embodiment, it is preferable that the resonator 40 has a rectangular shape in which in a plan view, the outer edge on the side of the first support portion 44A is a short side and the outer edge on the side of the second support portion 44B is a long side, and that when an angle formed by the first imaginary line 501 passing through the center of the first metal bump 110 and the center of the second metal bump 120 in a plan view and the second imaginary line 502 along the short side is set to be θ, a relational expression of 40° ≤ θ ≤ 49° is satisfied. According to this configuration, since the angle θ is set to satisfy the above relational expression, the frequency fluctuation ΔF due to the mounting stress can be suppressed to 12.5 ppm or less and the deterioration of the vibration characteristics can be suppressed.

In addition, in the resonator device 100 of the present embodiment, it is preferable that the resonator 40 has a rectangular shape in which in a plan view, the outer edge on the side of the first support portion 44A is a short side and the outer edge on the side of the second support portion 44B is a long side, and that when an angle formed by the first imaginary line 501 passing through the center of the first metal bump 110 and the center of the second metal bump 120 in a plan view and the second imaginary line 502 along the short side is set to be θ, a relational expression of 42° ≤ θ ≤ 48° is satisfied. According to this configuration, since the angle θ is set to satisfy the above relational expression, the frequency fluctuation ΔF due to the mounting stress can be suppressed to 10 ppm or less and the deterioration of the vibration characteristics can be further suppressed.

In addition, in the resonator device 100 of the present embodiment, it is preferable that the first joining member and the second joining member are the metal bumps 110 and 120. According to this configuration, the resonator 40 and the base 10 are joined by using the metal bumps 110 and 120. Therefore, for example, as compared with a case where the resonator 40 and the base 10 are joined by an adhesive, the metal bumps 110 and 120 do not spread around, and thus the resonator 40 and the base 10 can be joined at a predetermined position and the joint strength can be improved.

Further, it is preferable that the resonator device 100 of the present embodiment further includes the oscillation circuit 200A that is disposed on the base 10 and excites the resonator 40. According to this configuration, the resonator device 100 including an oscillator, in which the strength of the resonator 40 can be maintained and the frequency fluctuation due to the mounting stress is reduced, can be provided.

Hereinafter, a modification example of the embodiments described above will be described.

The resonator is not limited to the configuration in which the other surface 40A2 side of the vibrating section 40A as described above faces the base 10. As in a resonator 404 illustrated in FIG. 12, a configuration may be made such that the one surface 40A1 side of the vibrating section 40A faces the base 10. In this case, although not illustrated in the drawing, the electrode drawn out from the second excitation electrode 43 is disposed to be turned around to the one surface 40A1 side of the second support portion 44B, and is joined to the base 10 via the metal bump 120.

As described above, the joining members are not limited to the metal bumps 110 and 120 made of gold, and may be, for example, conductive adhesives. In this manner, since the resonator 40 and the base 10 are joined by using the conductive adhesive, for example, as compared with a case where the resonator 40 and the base 10 are joined by the metal bumps 110 and 120, the conductive adhesive is soft to absorb stress, and thus the frequency fluctuation ΔF due to the mounting stress can be further reduced. There is no limitation to the conductive adhesive, and the resonator 40 and the base 10 may be joined by using polyimide, silicone, or the like.

As described above, the base 10 and the lid 20 that configure the resonator device 100 are not limited to being made of silicon, and may be made of, for example, ceramic or the like.

As described above, the resonator 40 is not limited to the resonator formed of the AT cut quartz crystal substrate, and may be formed of a quartz crystal substrate other than the AT cut quartz crystal substrate, for example, an X cut quartz crystal substrate, a Y cut quartz crystal substrate, a Z cut quartz crystal substrate, a BT cut quartz crystal substrate, an SC cut quartz crystal substrate, an ST cut quartz crystal substrate, or the like.

What is claimed is:

1. A resonator device comprising:
a resonator that includes a vibrating section that is a quadrangle including a first side and a second side intersecting with each other in a plan view, and a support section including a first portion along the first side and a second portion along the second side and having a thickness greater than a thickness of the vibrating section;
a base to which the resonator is attached;
a first joining member that is disposed in a region overlapping the first portion of the resonator in a plan view and joins the resonator and the base; and
a second joining member that is disposed in a region overlapping the second portion of the resonator in a plan view and joins the resonator and the base.

2. The resonator device according to claim 1, wherein
the resonator has a rectangular shape in which in a plan view, an outer edge on a side of the first portion is a short side and an outer edge on a side of the second portion is a long side, and
when in a plan view, an angle formed by a first imaginary line passing through a center of the first joining member and a center of the second joining member and a second imaginary line along the short side is set to be θ, a relational expression of 40° ≤ θ ≤ 49° is satisfied.

3. The resonator device according to claim 1, wherein
the resonator has a rectangular shape in which in a plan view, an outer edge on a side of the first portion is a short side and an outer edge on a side of the second portion is a long side, and
when in a plan view, an angle formed by a first imaginary line passing through a center of the first joining member and a center of the second joining member and a second imaginary line along the short side is set to be θ, a relational expression of 42° ≤ θ ≤ 48° is satisfied.

4. The resonator device according to claim 1, wherein
the first joining member and the second joining member are metal bumps.

5. The resonator device according to claim 1, wherein
the first joining member and the second joining member are conductive adhesives.

6. The resonator device according to claim 1, further comprising:
an oscillation circuit that is disposed on the base and excites the resonator.
